(19) United States
(12) Patent Application Publication
(10) Pub. No.: US 2005/0269562 A1
(43) Pub. Date: Dec. 8, 2005

(54) Thin film transistor (TFT) and flat display panel having the thin film transistor (TFT)

(76) Inventors: Nam-Choul Yang, Suwon-si (KR); Hye-Dong Kim, Suwon-si (KR); Min-Chul Suh, Suwon-si (KR); Jae-Bon Koo, Suwon-si (KR); Sang-Min Lee, Suwon-si (KR)

Correspondence Address: Robert E. Bushnell, Suite 300, 1522 K Street, N.W., Washington, DC, 20005-1202, US

(21) Appl. No.: 11/126,300

(22) Filed: May 11, 2005

(30) Foreign Application Priority Data
Jun. 8, 2004 (KR) 10-2004-0041975

(51) Int. Cl. G02F 1/136

(52) U.S. Cl. 257/40

(57) ABSTRACT

A Thin Film Transistor (TFT) includes: a gate electrode; a source electrode and a drain electrode each insulated from the gate electrode; and an organic semiconductor layer adapted to contact each of the source and drain electrodes, the organic semiconductor layer being insulated from the gate electrode; wherein the organic semiconductor layer includes a boundary region having a smaller grain size than other portions of the organic semiconductor layer, the boundary region being arranged around at least a channel region and a source and drain region of the organic semiconductor layer.

### CLAIM OF PRIORITY

This application makes reference to, incorporates the same herein, and claims all benefits accruing under 35 U.S.C. §119 from an application for THIN FILM TRANSISTOR AND FLAT DISPLAY PANEL HAVING THE SAME earlier filed in the Korean Intellectual Property Office on Jun. 8, 2004 and there duly assigned Serial No. 10-2004-0041975.

### BACKGROUND OF THE INVENTION

1. Field of the Invention

The present invention relates to a Thin Film Transistor (TFT) and a flat display panel having the TFT, and more particularly, to a TFT that can simply provide a patterning effect on a semiconductor layer and a flat display panel having the same.

2. Description of the Related Art

Thin Film Transistors (TFTs) used in Liquid Crystal Display (LCD) devices, Organic Electro Luminescence Display (OELD) devices, or Inorganic Electro Luminescent Display (IELD) devices are used as switching devices that control the operation of pixels and driving devices for driving the pixels in display devices.

The TFT includes a semiconductor layer having source/drain regions doped with a high concentration of a dopant and a channel region formed between the source/drain region, a gate electrode disposed on a region corresponding to the channel region and insulated from the semiconductor layer, and source/drain electrodes contacting each of the source/drain regions.

A recent flat display device should be flexible as well as thin. To obtain a flexible display device, many attempts have been made to use plastic substrates instead of conventional glass substrates. When a plastic substrate is used, a low temperature process must be used. Therefore, there is a drawback in that a conventional polysilicon thin film cannot be used.

To solve this problem, recently, the use of organic semiconductors have been introduced. Therefore, a low price TFT can be manufactured since organic semiconductors can be formed by a low temperature process.

However, organic semiconductors cannot be patterned by a conventional photolithography method. That is, patterning is required for forming an active channel. However, when the patterning is performed by a conventional wet or dry etching process, the organic semiconductor can be damaged by the etching process.

Therefore, a new patterning method for patterning a semiconductor layer is required.

### SUMMARY OF THE INVENTION

The present invention provides a TFT that includes patterning on a semiconductor layer and a flat display panel having the TFT.

According to one aspect of the present invention, a Thin Film Transistor (TFT) is provided, the TFT comprising: a gate electrode; a source electrode and a drain electrode each insulated from the gate electrode; and an organic semiconductor layer adapted to contact each of the source and drain electrodes, the organic semiconductor layer being insulated from the gate electrode; wherein the organic semiconductor layer includes a boundary region having a smaller grain size than other portions of the organic semiconductor layer, the boundary region being arranged around at least a channel region and a source and drain region of the organic semiconductor layer.

The roughness of a lower part of the organic semiconductor layer contacting the boundary region of the organic semiconductor layer is preferably greater than roughness of other lower parts of the organic semiconductor layer contacting other portions of the organic semiconductor layer.

The TFT preferably further comprises an insulating film adapted to cover the gate electrode, the organic semiconductor layer being arranged on the insulating film; wherein roughness of the insulating film corresponding to the boundary region of the organic semiconductor layer is greater than roughness of other portions of the insulating film corresponding to other portions of the organic semiconductor layer.

The TFT preferably further comprises: an insulating film adapted to cover the gate electrode, the source and drain electrodes being arranged on the insulating film; a protection film having an opening corresponding to the gate electrode and adapted to cover the insulating film and source and drain electrodes; wherein the organic semiconductor layer is arranged on the protection film; and wherein roughness of the protection film corresponding to the boundary region of the organic semiconductor layer is greater than roughness of other portions of the protection film corresponding to other portions of the organic semiconductor layer.

The TFT preferably further comprises an organic light emitting film; wherein the source and drain electrodes are arranged on the substrate; wherein the organic light emitting film is arranged on the substrate to cover the source and drain electrodes; and wherein a portion of the substrate corresponding to the boundary region of the organic semiconductor layer has a greater surface roughness than other portions of the substrate corresponding to other portions of the organic semiconductor layer.

The organic semiconductor layer preferably includes at least a material consisting of pentacene, tetracene, anthracene, naphthalene, a-6-thiophene, a-4-thiophene, perylene and their derivatives, rubrene and its derivatives, coronene and its derivatives, perylene tetracarboxylic diimide and its derivatives, perylene tetracarboxylic dianhydride and its derivatives, oligoacene of naphthalene and its derivatives, a-5-oligothiophene of thiophene and its derivatives, phthalocianin and its derivatives, pyromellitic dianhydride and its derivatives, and pyromellitic diimide and its derivatives.

According to another aspect of the present invention, a flat display device including a Thin Film Transistor (TFT) is provided, the TFT comprising: a gate electrode; a source electrode and a drain electrode each insulated from the gate electrode; and an organic semiconductor layer adapted to contact each of the source and drain electrodes, the organic semiconductor layer being insulated from the gate electrode; wherein the organic semiconductor layer includes a boundary region having a smaller grain size than other portions of the organic semiconductor layer, the boundary region being arranged around at least a channel region and a source and drain region of the organic semiconductor layer.

According to yet another aspect of the present invention, a Thin Film Transistor (TFT) is provided, the TFT comprising: a gate electrode; a source electrode and a drain electrode each insulated from the gate electrode; an organic semiconductor layer adapted to contact each of the source and drain electrodes, the organic semiconductor layer being insulated from the gate electrode; and a surface-treated portion having a greater surface roughness than other portions on a same plane, the surface-treated portion being arranged at least peripherally of a channel region of the organic semiconductor layer to contact a lower portion of the organic semiconductor layer.

The TFT preferably further comprises an insulating film arranged to cover the gate electrode; the organic semiconductor layer being arranged on the insulating film, and the surface-treated portion being arranged on the insulating film.

The TFT preferably further comprises: an insulating film arranged to cover the gate electrode, the source and drain electrodes being arranged on the insulating film; and a protection film having an opening corresponding to the gate electrode, the protection film being arranged to cover the insulating film and the source and drain electrodes, the organic semiconductor layer being arranged on the protection film; wherein the surface-treated portion is arranged on the protection film.

The source and drain electrodes are preferably arranged on the substrate, the organic semiconductor layer are arranged to cover the source and drain electrodes on the substrate, and the surface-treated portion is arranged on the substrate.

A grain size of the organic semiconductor layer contacting the surface-treated portion is preferably less than that of the organic semiconductor layer not contacting the surface-treated portion.

The surface-treated portion preferably comprises a metal.

The organic semiconductor layer preferably includes at least a material consisting of pentacene, tetracene, anthracene, naphthalene, a-6-thiophene, a-4-thiophene, perylene and their derivatives, rubrene and its derivatives, coronene and its derivatives, perylene tetracarboxylic diimide and its derivatives, perylene tetracarboxylic dianhydride and its derivatives, oligoacene of naphthalene and its derivatives, a-5-oligothiophene of thiophene and its derivatives, phthalocianin and its derivatives, pyromellitic dianhydride and its derivatives, and pyromellitic diimide and its derivatives.

According to still another aspect of the present invention, a flat display device that includes a Thin Film Transistor (TFT) comprising: a gate electrode; a source electrode and a drain electrode each insulated from the gate electrode; an organic semiconductor layer adapted to contact each of the source and drain electrodes, the organic semiconductor layer being insulated from the gate electrode; and a surface-treated portion having a greater surface roughness than other portions on a same plane, the surface-treated portion being arranged at least peripherally of a channel region of the organic semiconductor layer to contact a lower portion of the organic semiconductor layer.

### BRIEF DESCRIPTION OF THE DRAWINGS

A more complete appreciation of the present invention, and many of the attendant advantages thereof, will be readily apparent as the present invention becomes better understood by reference to the following detailed description when considered in conjunction with the accompanying drawings in which like reference symbols indicate the same or similar components, wherein:

FIG. 1 is a cross-sectional view of a structure of a TFT according to an embodiment of the present invention;

FIG. 2 is a photograph of grains of a pentacene organic layer grown on a Pd film having a low surface roughness;

FIG. 3 is a photograph of grains of a pentacene organic layer grown on a Pd film having a high surface roughness;

FIG. 4 is a cross-sectional view of a structure of a TFT according to another embodiment of the present invention;

FIG. 5 is a cross-sectional view of a structure of a TFT according to still another embodiment of the present invention;

FIGS. 6 and 7 are cross-sectional views of a structure of a TFT using a metal pattern according to another embodiment of the present invention; and

FIG. 8 is a cross-sectional view of an OELD device to which the TFT of FIG. 1 is applied.

### DETAILED DESCRIPTION OF THE INVENTION

The present invention will now be described more fully with reference to the accompanying drawings in which exemplary embodiments of the present invention are shown.

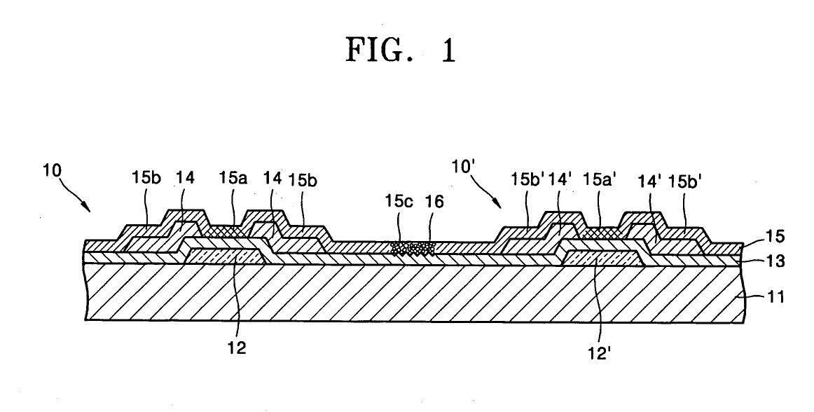

FIG. 1 is a cross-sectional view of a structure of a TFT according to an embodiment of the present invention.

Referring to FIG. 1, the TFTs 10 and 10′ according to the present invention are included on a substrate 11. The substrate 11 can be formed of glass, plastic or a metal, a surface of which is processed with an insulator. The TFTs 10 and 10′ formed on the substrate 11 are formed close to each other and have an identical structure. First, the TFT 10 will now be described.

A gate electrode 12 having a predetermined pattern is formed on the substrate 11, and a gate insulating film 13 is formed to cover the gate electrode 12. Each of the source/drain electrodes 14 are formed on the gate insulating film 13. The source/drain electrodes 14, as depicted in FIG. 1, a predetermined portion can be formed to overlap the gate electrode 12, but it is not limited thereto. An organic semiconductor layer 15 is formed on an entire upper part of the source/drain electrodes 14.

The organic semiconductor layer 15 includes source/drain regions 15b and a channel region 15a that connects the source and drain regions 15b. The organic semiconductor layer 15 can be formed of an n-type or p-type organic semiconductor and the source/drain regions 15b can be doped only with an n-type or p-type dopant.

The organic semiconductor layer 15 can be formed of a material selected from the group consisting of pentacene, tetracene, anthracene, naphthalene, a-6-thiophene, a-4-thiophene, perylene and their derivatives, rubrene and its derivatives, coronene and its derivatives, perylene tetracarboxylic diimide and its derivatives, perylene tetracarboxylic dianhydride and its derivatives, oligoacene of naphthalene and its derivatives, a-5-oligothiophene of thiophene and its derivatives, phthalocianin that can or can not contain a metal and its derivatives, pyromellitic dianhydride and its derivatives, and pyromellitic diimide and its derivatives.

As depicted in FIG. 1, since the organic semiconductor layer 15 is deposited on the entire surface of the source/drain electrodes 14, if the organic semiconductor layer 15 is not patterned additionally, cross-talk can occur between the adjacent TFTs 10 and 10′.

To prevent cross-talk between the adjacent TFTs 10 and 10′, a boundary region 15c having a smaller grain size than other portion is interposed between the adjacent TFTs 10 and 10′.

Thus, the boundary region 15c raises the patterning effect of the organic semiconductor layer 15 since the boundary region 15c is disposed around the channel region 15a. Therefore, the boundary region 15c can be formed as a closed loop that surrounds the TFT 10 or can be formed in a plurality of straight lines that are not connected to each other.

The boundary region 15c having a smaller grain size than other regions is formed in the organic semiconductor layer 15 to prevent the migration of carriers through the boundary region 15c by increasing its resistance compared with the resistance of the other regions.

In the organic semiconductor layer 15, if the grain size is small, the grain boundary becomes larger, and then, the resistance increases by increasing the trap site. That is, as the grain size decreases in the boundary region 15c, the boundary region 15c forms a barrier. Accordingly, the patterning effect between the adjacent TFTs can be obtained.

The boundary region 15c having a smaller grain size can be obtained in many ways. According to an embodiment of the present invention, a boundary region 15c having a smaller grain size can be formed in the organic semiconductor layer 15 by forming a surface-treated portion 16 under a lower part of the organic semiconductor layer 15 corresponding to the boundary region 15c.

In the organic semiconductor layer 15, the size of the grain can vary according to the morphology of material, such as a surface roughness, which contacts the lower part of the organic semiconductor layer 15. That is, the greater the roughness of the material contacting the lower part of the organic semiconductor layer 15, the larger the number of small grains formed, because a large number of seeds are formed when depositing the organic semiconductor layer 15 and the seeds can not grow to large size grains.

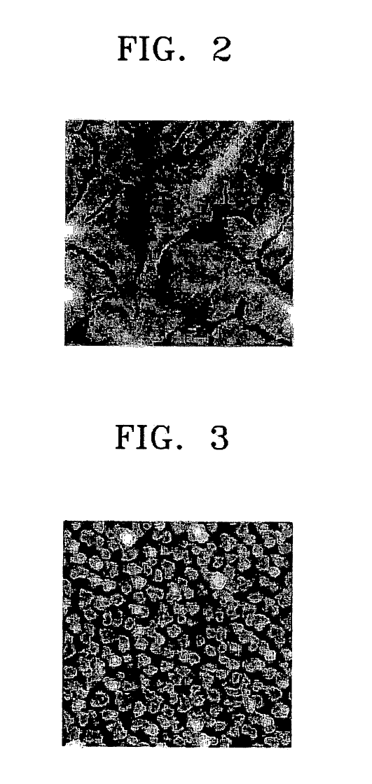

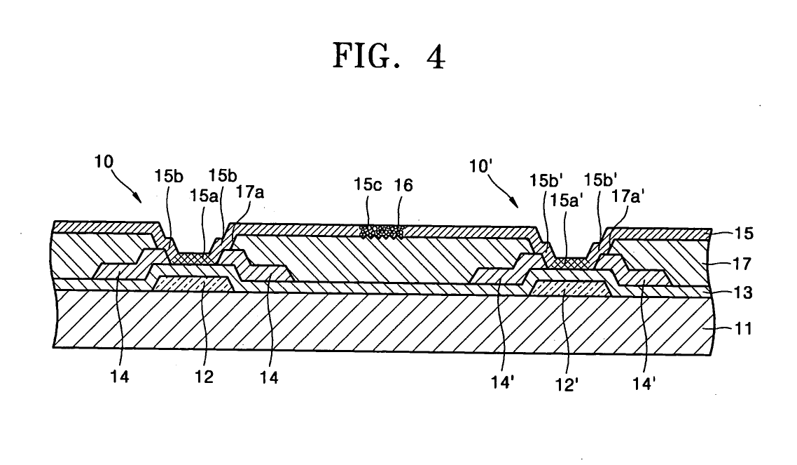

FIGS. 2 and 3 are photographs showing grains of a pentacene organic layer grown on a Pd film which has a low surface roughness and a high surface roughness, respectively. The surface roughness of the Pd film in FIG. 2 is 11 Å/s, and that of the Pd film in FIG. 3 is 48 Å/s. As shown in FIGS. 2 and 3, the grain size of the organic semiconductor layer 15 grown on the high roughness Pd film is smaller than that of the organic semiconductor layer 15 grown on the low roughness of Pd film.

This result has been disclosed by Knipp et al. in Journal of Applied Physics. vol.93, No.1, Jan. 1, 2003.

An aspect of the present invention is to form the boundary region 15c in the organic semiconductor layer 15 using the above characteristic of the organic semiconductor layer 15. According to the formation of the boundary region 15c, a patterning effect that separates the adjacent TFTs from each other without performing an additional patterning can be obtained.

As depicted in FIG. 1, when forming a multiple number of TFTs 10 and 10′ for constructing a particular circuit, the boundary region 15c is formed on the surface-treated portion 16 by forming a predetermined surface-treated portion 16 on a region for forming the boundary region 15c among surfaces of the gate insulating film 13 on which the organic semiconductor layer 15 is formed.

The surface-treated portion 16 has a rougher surface than other portions by plasma processing a surface of an insulating film, such as the gate insulating film 13. The magnitude of surface roughness difference can be determined by considering the resistance in the boundary region 15c and can be in a range of 2-50 times greater than that of the channel region 15a.

In this manner, the boundary region 15c having a smaller grain size than other portions can be formed in the organic semiconductor layer 15 by forming the surface-treated portion 16 directly under the organic semiconductor layer 15 around the channel regions 15a and 15a′ of the TFTs 10 and 10′, and eventually, a patterning effect between the adjacent TFTs can be obtained.

As shown in FIG. 1, in the case of the channel region 15a, large size grains are formed since the channel region 15a is located close to a portion of the gate insulating film 13 having less surface roughness than that of the surface-treated portion 16, thereby obtaining a high mobility characteristic.

The surface-treated portion 16 for forming the boundary region 15c is not necessarily formed on the gate insulating film 13, but can be formed anywhere as long as it contacts the lower part of the organic semiconductor layer 15.

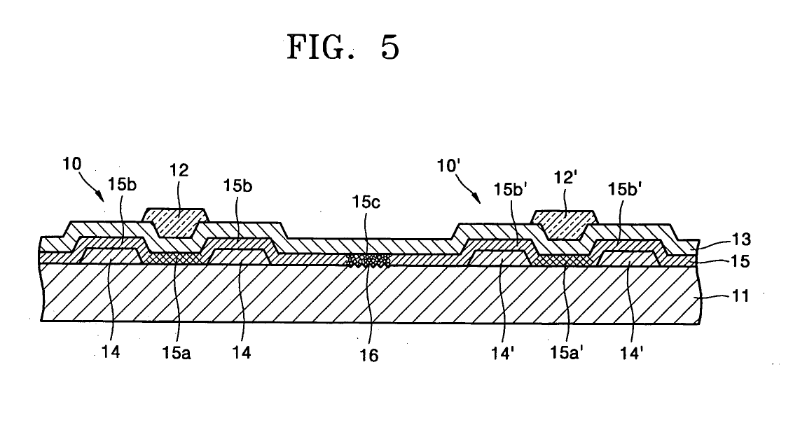

FIG. 4 is a cross-sectional view illustrating a structure of a TFT according to another embodiment of the present invention, in which the surface-treated portion 16 is formed on an upper part of an additional protection film 17. In FIG. 4, the protection film 17 is formed to cover the source/drain electrodes 14 and 14′ and the channel regions 15a and 15a′ can be formed in predetermined openings 17a and 17a′ in the protection film 17. At this time, the organic semiconductor layer 15 is formed on the protection film 17.

Inorganic materials that can be used for forming the gate insulating film 13 or the protection film 17, on which the surface-treated portion 16 can be formed, can be selected form the group consisting of SiO₂, SiNx, Al₂O₃, TiO₂, Ta₂O₅, HfO₂, ZrO₂, BST, or PZT, and organic materials can be a ordinary polymer, such as PMMA or PS, polymer derivatives having phenol group, acryl polymers, imid polymers, arylester polymers, amide polymers, fluoride polymers, p-xylene polymers, vinyl alcohol polymers, and a blend of these materials. An inorganic-organic stacking film can also be used.

SAM, such as OTS or HMDS, or coating a super thin film of fluoride polymer or ordinary polymer can be processed on the uppermost part of the gate insulating film 13 or the protection film 17 adjacent to the organic semiconductor layer 15.

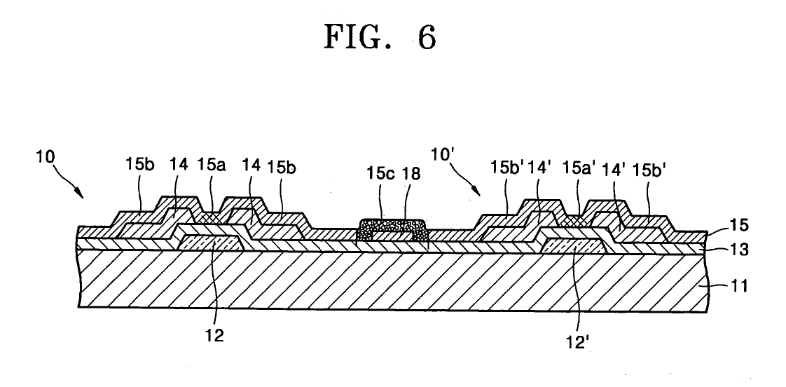

FIG. 5 is a cross-sectional view illustrating a structure of a TFT according to still another embodiment of the present invention, in which the surface-treated portion 16 is formed on the substrate 11. This is a case when the surface-treated portion 16 is applied to a staggered structure TFT.

That is, the source/drain electrodes 14 and 14′ are formed on the substrate 11 and the organic semiconductor layer 15 is formed to cover the source/drain electrodes 14 and 14′. The gate insulating film 13 is formed to cover the organic semiconductor layer 15, and the gate electrodes 12 and 12′ are formed on regions corresponding to the channel regions 15a and 15a′ of the organic semiconductor layer 15.

At this time, the boundary region 15c between the TFTs 10 and 10′ can be formed by interposing the surface-treated portion 16 between the TFTs 10 and 10′.

The uppermost part of the substrate 11 adjacent to the organic semiconductor layer 15 can be SAM processed, such as OTS or HMDS, or can be coated with a super thin film of a fluoride polymer or an ordinary polymer.

The surface-treated portion 16 can also be applied to a variety of TFT structures.

The boundary region 15c of the present invention cannot only be obtained by the surface-treated portion 16 formed in the gate insulating film 13 or the protection film 17.

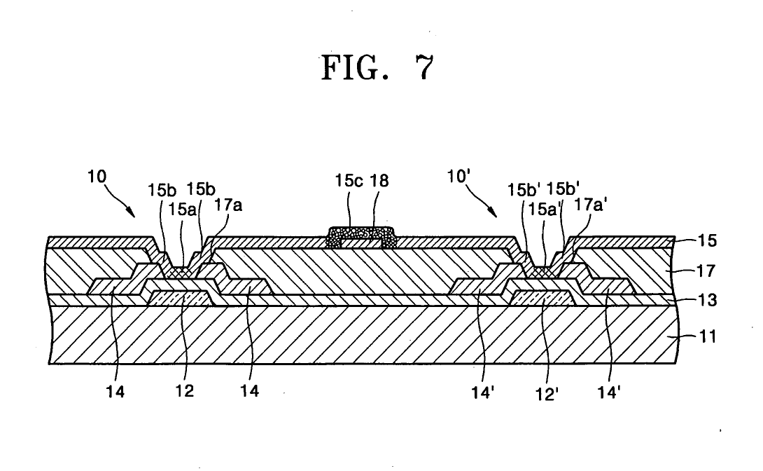

That is, as depicted in FIGS. 6 and 7, the boundary region 15c is formed on a metal pattern 18 by forming the metal pattern 18 around the channel region 15a. The metal pattern 18 has a greater roughness than the gate insulating film 13 or the protection film 17, thereby forming the boundary region 15c by the aforementioned principle.

Accordingly, the patterning effect of the organic semiconductor layer 15 can be obtained by forming the boundary region 15c between the adjacent TFTs 10 and 10′ by the metal pattern 18.

At this time, as depicted in FIG. 6 and 7, the metal pattern 18 can also be formed on the gate insulating film 13 and on the additional protection film 17, respectively.

The metal pattern 18 can also be formed by depositing an additional metal film or a metal film like the source/drain electrodes or wirings.

The metal pattern 18 can also be applied to a staggered TFT structure as depicted in FIG. 5. That is, in the staggered TFT structure in FIG. 5, the boundary region 15c can be formed by forming the metal pattern 18 on the substrate 11.

The TFT according to the present invention can be formed not only on a stacking structure as described above but also on a variety of stacking structures.

The structure of the TFT as described above can be applied to flat display devices, such as LCDs or OELD display devices.

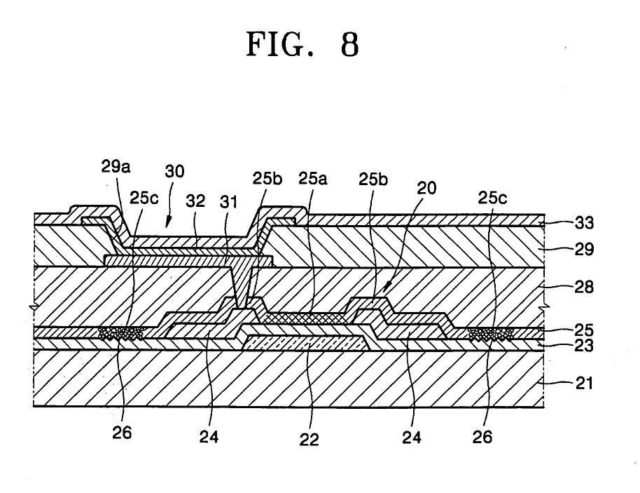

As an example, FIG. 8 is a cross-sectional view illustrating an OELD device to which the TFT of FIG. 1 is applied.

In FIG. 8, one sub-pixel of the OELD is depicted. Each sub-pixel includes the OELD (hereinafter, EL device) as a self-luminant device and at least more than one TFT. The sub-pixel also includes an additional capacitor (not shown).

The OELD can have a variety of pixel patterns according to the color of the EL device (OLED). The OELD preferably includes sub-pixels of red, green, and blue.

Each of the sub-pixels of red R, green G, and blue B hasa TFT structure as depicted in FIG. 8, an EL device (OLED) as a self-luminant, and a TFT. The TFT can be the TFT according to the aforementioned embodiments of the present invention. However, the TFT is not limited thereto, but it can include a variety of structures.

As shown in FIG. 8, the aforementioned TFT is disposed on an insulating substrate 21.

As depicted in FIG. 8, the TFT 20 includes a gate electrode 22 having a predetermined pattern on a substrate 21, a gate insulating film 23 formed to cover the gate electrode 22, and source/drain electrodes 24 on the gate insulating film 23. At this time, as described above, a surface-treated portion 26 (not shown) is formed on the gate insulating film 23. The detailed descriptions of the surface-treated portion 26 will be omitted since the embodiments are the same as in the above descriptions.

Upper parts of the source/drain electrodes 24 and the surface-treated portion 26 are covered by an organic semiconductor layer 25.

The organic semiconductor layer 25 includes source/drain regions 25b and a channel region 25a that connects the source/drain regions 25b. A boundary region 25c is formed on the surface-treated portion 26 in the organic semiconductor layer 25.

A passivation film 28 is formed to cover the TFT 20 after forming the organic semiconductor layer 25. The passivation film 28 is formed in a single or a multiple layer, and can be formed of an organic material, an inorganic material, or a composite of organic/inorganic materials.

A pixel electrode 31 as one electrode of an EL device 30 is formed on the passivation film 28 and a defining layer 29 is formed on the pixel electrode 31. Afterward, an organic light emitting film 32 of the EL device 30 is formed after forming a predetermined opening 29a in the defining layer 29.

The EL device 30 displays a predetermined image information by emitting red, green, or blue light according to the current flow, and comprises the pixel electrode 31 connected to one of the source/drain electrodes 24 of the TFT 20, a opposing electrode 33 formed to cover the entire pixels, and the organic light emitting film 32 that emits light and is disposed between the pixel electrode 31 and the opposing electrode 33.

The pixel electrode 31 and the opposing electrode 33 are insulated from each other by the organic light emitting film 32, and light is emitted form the organic light emitting film 32 by applying a voltage having different polarities to the organic light emitting film 32.

The organic light emitting film 32 can be formed of a low molecule organic or a polymer organic film. When it is formed of a low molecule organic film, a Hole Injection Layer (HIL), a Hole Transport Layer (HTL), an Emission layer (EML), an Electron Transport Layer (ETL), and an Electron Injection Layer (EIL) can be stacked in a single or a multiple layer structure. The organic light emitting film 32 can be formed of an organic material selected from the group consisting of copper phthalocyanine (CuPc), (N,N′-Di(naphthalene-1-yl)-N,N′-diphenyl-benzidine (NPB), or tris-8-hydroxyquinoline aluminum)(Alq3). The low molecule organic film is formed by a vacuum deposition method.

In the case of the polymer organic film, the organic light emitting film 32 can have a structure that includes a HTL and an EML. At this time, a PEDOT is used as the HTL and an organic polymer, such as Poly-Phenylenevinylene (PPV) and Polyfluorene group, can be used as the EML, and the poltmer organic film can be formed by a screen printing method or an ink jet printing method.

The organic films are not limited thereto, but they can be applied to a variety of embodiments.

The pixel electrode 31 can function as an anode and the opposing electrode 33 can function as a cathode, but the polarity of the pixel electrode 31 and the facing electrode 33 can be reversed.

The present invention is not limited to the above structure, but a variety of structures of the OELD can be applied.

However, in the case of an LCD, the manufacturing of a lower substrate of the LCD device is completed by forming a lower orientation film (not shown) that covers the pixel electrode 31.

As described above, the TFT according to the present invention can be mounted on each of the pixels as depicted in FIG. 8 or can be mounted on a driver circuit (not shown) that does not implement an image.

A flexible plastic substrate is suitable for the substrate 21 of the OELD device.

According to the present invention, the following effects can be obtained.

First, a patterning effect that separates TFTs adjacent to each other can be obtained by the grain size difference without performing an additional patterning process on an organic semiconductor layer. Therefore, a complicated patterning process can be omitted.

Second, the reduction of characteristics of an active channel can be minimized since a dry or wet etching process is not performed.

Third, the processing time can be reduced and the efficiency of process can be increased since it is unnecessary to etch the entire surface of the organic semiconductor layer except the active channel region. Also, since a wet etching process accompanied by the patterning process is not performed, the process can be simplified and the efficiency thereof can be increased.

Fourth, a leakage current can be reduced by separating the channel region from the adjacent TFTs.

Fifth, the mobility characteristic can be improved by increasing the grain size of the channel region.

While the present invention has been particularly shown and described with reference to exemplary embodiments thereof, it will be understood by those of ordinary skill in the art that various changes in form and details can be made therein without departing from the spirit and scope of the present invention as defined by the following claims.

1. A Thin Film Transistor (TFT) comprising:
a gate electrode;
a source electrode and a drain electrode each insulated from the gate electrode; and
an organic semiconductor layer adapted to contact each of the source and drain electrodes, the organic semiconductor layer being insulated from the gate electrode;
wherein the organic semiconductor layer includes a boundary region having a smaller grain size than other portions of the organic semiconductor layer, the boundary region being arranged around at least a channel region and a source and drain region of the organic semiconductor layer.

2. The TFT of claim 1, wherein roughness of a lower layer contacting the boundary region of the organic semiconductor layer is greater than roughness of other lower parts of the organic semiconductor layer contacting other portions of the organic semiconductor layer.

3. The TFT of claim 1, further comprising an insulating film adapted to cover the gate electrode, the organic semiconductor layer being arranged on the insulating film;
wherein roughness of the insulating film corresponding to the boundary region of the organic semiconductor layer is greater than roughness of other portions of the insulating film corresponding to other portions of the organic semiconductor layer.

4. The TFT of claim 1, further comprising:
an insulating film adapted to cover the gate electrode, the source and drain electrodes being arranged on the insulating film;
a protection film having an opening corresponding to the gate electrode and adapted to cover the insulating film and source and drain electrodes;
wherein the organic semiconductor layer is arranged on the protection film; and
wherein roughness of the protection film corresponding to the boundary region of the organic semiconductor layer is greater than roughness of other portions of the protection film corresponding to other portions of the organic semiconductor layer.

5. The TFT of claim 1;
wherein the source and drain electrodes are arranged on the substrate;
wherein the organic semiconductor layer is arranged on the substrate to cover the source and drain electrodes; and
wherein a portion of the substrate corresponding to the boundary region of the organic semiconductor layer has a greater surface roughness than other portions of the substrate corresponding to other portions of the organic semiconductor layer.

6. The TFT of claim 1, wherein the organic semiconductor layer includes at least a material consisting of pentacene, tetracene, anthracene, naphthalene, a-6-thiophene, a-4-thiophene, perylene and their derivatives, rubrene and its derivatives, coronene and its derivatives, perylene tetracarboxylic diimide and its derivatives, perylene tetracarboxylic dianhydride and its derivatives, oligoacene of naphthalene and its derivatives, a-5-oligothiophene of thiophene and its derivatives, phthalocianin and its derivatives, pyromellitic dianhydride and its derivatives, and pyromellitic diimide and its derivatives.

7. A flat display device including a Thin Film Transistor (TFT), the TFT comprising:
a gate electrode;
a source electrode and a drain electrode each insulated from the gate electrode; and
an organic semiconductor layer adapted to contact each of the source and drain electrodes, the organic semiconductor layer being insulated from the gate electrode;
wherein the organic semiconductor layer includes a boundary region having a smaller grain size than other portions of the organic semiconductor layer, the boundary region being arranged around at least a channel region and a source and drain region of the organic semiconductor layer.

8. A Thin Film Transistor (TFT) comprising:
a gate electrode;
a source electrode and a drain electrode each insulated from the gate electrode;
an organic semiconductor layer adapted to contact each of the source and drain electrodes, the organic semiconductor layer being insulated from the gate electrode; and
a surface-treated portion having a greater surface roughness than other portions on a same plane, the surface-treated portion being arranged at least peripherally of a channel region of the organic semiconductor layer to contact a lower portion of the organic semiconductor layer.

9. The TFT of claim 8, further comprising an insulating film arranged to cover the gate electrode; the organic semiconductor layer being arranged on the insulating film, and the surface-treated portion being arranged on the insulating film.

10. The TFT of claim 8, further comprising:
an insulating film arranged to cover the gate electrode, the source and drain electrodes being arranged on the insulating film; and
a protection film having an opening corresponding to the gate electrode, the protection film being arranged to cover the insulating film and the source and drain electrodes, the organic semiconductor layer being arranged on the protection film;
wherein the surface-treated portion is arranged on the protection film.

11. The TFT of claim 8, wherein the source and drain electrodes are arranged on the substrate, the organic semiconductor layer are arranged to cover the source and drain electrodes on the substrate, and the surface-treated portion is arranged on the substrate.

12. The TFT of claim 8, wherein a grain size of the organic semiconductor layer contacting the surface-treated portion is less than that of the organic semiconductor layer contacting the other portion of the surface-treated portion.

13. The TFT of claim 8, wherein the surface-treated portion comprises a metal.

14. The TFT of claim 8, wherein the organic semiconductor layer includes at least a material consisting of pentacene, tetracene, anthracene, naphthalene, a-6-thiophene, a-4-thiophene, perylene and their derivatives, rubrene and its derivatives, coronene and its derivatives, perylene tetracarboxylic diimide and its derivatives, perylene tetracarboxylic dianhydride and its derivatives, oligoacene of naphthalene and its derivatives, a-5-oligothiophene of thiophene and its derivatives, phthalocianin and its derivatives, pyromellitic dianhydride and its derivatives, and pyromellitic diimide and its derivatives.

15. A flat display device that includes a Thin Film Transistor (TFT) comprising:
a gate electrode;
a source electrode and a drain electrode each insulated from the gate electrode;
an organic semiconductor layer adapted to contact each of the source and drain electrodes, the organic semiconductor layer being insulated from the gate electrode; and
a surface-treated portion having a greater surface roughness than other portions on a same plane, the surface-treated portion being arranged at least peripherally of a channel region of the organic semiconductor layer to contact a lower portion of the organic semiconductor layer.
